(19) United States
(12) Patent Application Publication
(10) Pub. No.: US 2010/0224862 A1
(43) Pub. Date: Sep. 9, 2010

(54) CARBON NANOTUBE STRUCTURE AND THIN FILM TRANSISTOR

(76) Inventors: Hiroyuki Endoh, Tokyo (JP); Satoru Toguchi, Tokyo (JP); Hideaki Numata, Tokyo (JP)

Correspondence Address: Mr. Jackson Chen, 6535 N. STATE HWY 161, IRVING, TX, 75039, US

(21) Appl. No.: 12/675,933

(22) PCT Filed: Sep. 2, 2008
(86) PCT No.: PCT/JP2008/065745

§ 371 Date: Mar. 1, 2010

(30) Foreign Application Priority Data
Sep. 7, 2007 (JP) 2007-232603

(51) Int. Cl. H01L 29/772; B32B 15/08

(52) U.S. Cl. 257/24; 428/327; 977/742; 257/E29.242

(57) ABSTRACT

When an electronic element using a carbon nanotube (CNT) is fabricated, particularly when a carbon nanotube thin film is formed on a previously formed electrode, a CNT film is manufactured on the previously formed electrode, and the CNT film on the electrode is used as an electronic element, as it is. In this case, a problem is that unless the carbon nanotubes and the electrode are in sufficient contact with each other, the contact resistance increases, and sufficient element properties are not obtained. When a carbon nanotube thin film is formed on a previously formed electrode, a conductive organic polymer thin film is formed, before or after the carbon nanotube thin film is manufactured, to decrease the contact resistance.

### TECHNICAL FIELD

The present invention relates to a carbon nanotube structure containing a carbon nanotube, or a thin film transistor comprising carbon nanotubes as a semiconductor layer. The present invention particularly relates to a thin film transistor in which a TFT (Thin Film Transistor) with low contact resistance between the carbon nanotubes and the electrodes, and with small variations in element properties against bending in a flexible device using a plastic substrate or the like can be obtained.

### BACKGROUND ART

Thin film transistors have been widely used as switching elements for display in liquid crystal displays and the like. Thin film transistors (hereinafter also referred to as TFTs) have been conventionally fabricated using amorphous and polycrystalline silicon. However, problems have been that CVD apparatuses used for the fabrication of such TFTs using silicon are very expensive, and that larger displays and the like using TFTs involve a significant increase in manufacturing cost. Another problem has been that since the process of forming a film of amorphous or polycrystalline silicon is performed at very high temperature, the types of materials that can be used as the substrate are limited, and lightweight resin substrates and the like cannot be used.

TFTs using organic substances or carbon nanotubes, instead of amorphous and polycrystalline silicon, to solve the above problems have been proposed. Vacuum deposition, coating, and the like have been known as film formation methods used when TFTs are formed with organic substances or carbon nanotubes. With these film formation methods, larger elements can be achieved while an increase in cost is suppressed, and the process temperature required during film formation can be relatively low. Therefore, in the TFTs using organic substances or carbon nanotubes, such an advantage is obtained that there are few limitations when the material used for the substrate is selected, and the practical use of the TFTs is expected.

However, in the TFTs using organic materials, the organic materials have significantly lower semiconductor properties than silicon materials, and therefore, it is difficult to obtain practical TFT properties.

On the other hand, the TFTs using carbon nanotubes have been actively studied because there is a possibility that TFTs with high performance can be manufactured. Reports described in Non-Patent Documents 1 to 5 show TFTs using carbon nanotubes, and show that the TFTs using carbon nanotubes exhibit performance equal to or higher than that of silicon.

When carbon nanotubes are used as the semiconductor material of the channel, a TFT is manufactured with one or several carbon nanotubes, or with many carbon nanotubes dispersed. When one or several carbon nanotubes are used, generally, carbon nanotubes with a length of about 1 μm or less are often used. Therefore, micromachining is required when a TFT is made, and it is necessary to manufacture a TFT with the so-called channel length, between the source electrode and the drain electrode, on a submicron scale. On the other hand, when many carbon nanotubes are used, a network of carbon nanotubes is used as the channel, and therefore, the channel length can be increased, and a TFT can be conveniently manufactured. Examples of reports on manufacturing a TFT with many carbon nanotubes dispersed include Non-Patent Document 5 and the like.

To form a thin film with many carbon nanotubes dispersed, a thin film can be easily formed when a solution or dispersion of carbon nanotubes is used. Reports described in Non-Patent Documents 6 to 9 show methods for forming a thin film of carbon nanotubes from a solution or a dispersion.

Carbon nanotubes are used as the material of the semiconductor layer, and a thin film of carbon nanotubes is formed in a step using a dispersion of carbon nanotubes. Thus, hard materials, such as glass, of course, and resins and plastics can be applied to the substrates of elements and devices, thereby, the entire element can have flexibility, and application to flexible TFTs can also be expected. Further, a coating process can be used, and therefore, there is a possibility that lower costs of elements and devices can be achieved by manufacturing methods to which coating processes and printing processes are applied.

Here, a cross-sectional structure of a typical carbon nanotube TFT is shown in FIG. 1. This TFT comprises a gate electrode (layer) 14 and an insulator layer 16 in this order on a substrate 11, and comprises a source electrode 12 and a drain electrode 13 formed on the insulator layer 16 at a predetermined interval. A carbon nanotube layer 15 is formed on the insulator layer 16 including part of the surfaces of the source electrode 12 and the drain electrode 13 and exposed between the source electrode 12 and the drain electrode 13. In the TFT with such a configuration, the carbon nanotube layer 15 forms a channel region, and on/off operation is performed by current flowing between the source electrode 12 and the drain electrode 13 being controlled by voltage applied to the gate electrode 14.

### Non-Patent Document 1: S. J. Tans, A. R. M. Verschueren, C. Dekker, NATURE, No. 393, p. 49, 1998

Non-Patent Document 2: R. Martel, T. Schmidt, H. R. Shea, T. Hertel, P. Avouris, Appl. Phys. Lett., vol. 73, No. 17, p. 2447, 1998
Non-Patent Document 3: S. J. wind, J. Appenzeller, R. Martel, V. Derycke, P. Avouris, Appl. Phys. Lett., vol. 80, No. 20, p. 3817, 2002
Non-Patent Document 4: K. Xiao, Y. Liu, P. Hu, G. Yu, X. Wang, D. Zhu, Appl. Phys. Lett., vol. 83, No. 1, p. 150, 2003
Non-Patent Document 5: S. Kumar, G. B. Blanchet, M. S. Hybertsen, J. Y. Murthy, M. A. Alam, Appl. Phys. Lett., vol. 89, p. 143501, 2006
Non-Patent Document 6: N. Saran, K. Parikh, D. Suh, E. Munoz, H. Kolla, S. K. Manohar, J. Am. Chem. Soc., vol. 126, p. 4462, 2004

### Non-Patent Document 7: Z. Wu, Z. Chen, X. Du, J. M. Logan, J. Sippel, M. Nikolou, K. Kamaras, J. R. Reynolds, D. B. Tanner, A. F. Hebard, A. G. Rinzler, SCIENCE, No. 305, p. 1273, 2004

### Non-Patent Document 8: M. Zhang, S. Fang, A. A. Zakhidov, S. B. Lee, A. E. Aliev, C. D. Williams, K. R. Atkinson, R. H. Baughman, SCIENCE, No. 309, p. 1215, 2005

Non-Patent Document 9: Y. Zhou, L. Hu, G. Gruner, Appl. Phys. Lett., vol. 88, p. 123109, 2006

### DISCLOSURE OF THE INVENTION

### Problems to be Solved by the Invention

When the above carbon nanotube TFT is to be manufactured, the location of the gate electrode, the gate insulating film, the source electrode and the drain electrode, and the carbon nanotube channel can be freely set. Either a bottom gate structure in which the gate electrode and the gate insulating film are fabricated first, or a top gate structure in which the gate electrode and the gate insulating film are fabricated later may be used. Also, either a bottom contact structure in which the carbon nanotube channel is fabricated after the source electrode and the drain electrode are fabricated, or a top contact structure in which the source electrode and the drain electrode are fabricated after the carbon nanotube channel is fabricated. However, particularly when the carbon nanotube channel is fabricated from a solution or dispersion of carbon nanotubes, a bottom gate and bottom contact structure in which a coating step can be performed after other structures are previously fabricated is preferably selected. Thus, the carbon nanotube TFT can be conveniently manufactured.

At this time, the carbon nanotube thin film is formed on the source electrode or the drain electrode. A carbon nanotube has a very elongated shape with a diameter on the order of nanometers and a length on the order of micrometers. Therefore, when the carbon nanotube thin film is formed on the source electrode or the drain electrode, it is very difficult to laminate the electrode and the carbon nanotubes in close contact. In the cases of TFTs and other electronic elements and devices, the contact resistance when different materials and thin films are bonded is very important, and unless two materials and thin films are firmly bonded physically and mechanically, the contact resistance increases, causing a decrease in element performance, and unstable element performance. Also, particularly in a case where a flexible material, such as plastic, is used for the substrate, when the substrate is bent and returned, the degree of contact between the electrode and the carbon nanotube changes, which causes a decrease in the properties of the element or the device against bending.

In view of the above, the present invention relates to a carbon nanotube structure in which a carbon nanotube thin film is formed later on an electrode, or a TFT comprising carbon nanotubes as a semiconductor layer. The present invention provides a carbon nanotube TFT with low contact resistance between the carbon nanotubes and the electrodes, and with small variations in element properties against bending in a flexible device using a plastic substrate or the like.

### Means for Solving the Problems

The carbon nanotube structure of the present invention is characterized by comprising a metal thin film, a carbon nanotube thin film, and an organic conductive polymer thin film, the carbon nanotube thin film and the organic conductive polymer thin film being in contact with each other.

Also, the thin film transistor of the present invention is a thin film transistor comprising source/drain electrodes spaced from each other, a channel, and a gate electrode spaced from the source/drain electrodes and being in contact with the channel via a gate insulating film, characterized by comprising the carbon nanotube structure comprising the source/drain electrodes as the metal thin film, in regions where the channel and the source/drain electrodes overlap.

### ADVANTAGES OF THE INVENTION

According to the carbon nanotube structure and carbon nanotube TFT of the present invention, it is possible to provide a carbon nanotube structure and a carbon nanotube TFT with low contact resistance between the electrode(s) and the carbon nanotube(s), and stable bending properties.

### BRIEF DESCRIPTION OF THE DRAWINGS

FIG. 1 is a cross-sectional view showing the configuration of a general TFT;

FIG. 2 is a cross-sectional view showing the state of a carbon nanotube ideally located on an electrode surface;

FIG. 3 is a cross-sectional view showing the state of a carbon nanotube obliquely located on an electrode surface;

FIG. 4A is a cross-sectional view showing the structure of a carbon nanotube structure of the present invention;

FIG. 4B is a cross-sectional view showing the structure of a carbon nanotube structure of the present invention;

FIG. 5A is a cross-sectional view showing a state when a general carbon nanotube structure is bent;

FIG. 5B is a cross-sectional view showing a state when a carbon nanotube structure of the present invention is bent;

FIG. 6A is a cross-sectional view showing the structure of a carbon nanotube TFT of the present invention; and

FIG. 6B is a cross-sectional view showing the structure of a carbon nanotube TFT of the present invention.

### DESCRIPTION OF SYMBOLS

11 substrate
12 source electrode
13 drain electrode
14 gate electrode
15 carbon nanotube thin film
16 insulator layer
17 organic conductive polymer thin film
18 carbon nanotube
19 metal thin film

### BEST MODE FOR CARRYING OUT THE INVENTION

As a result of studying diligently to solve the above-described problems, the present inventors have found that a decrease in contact resistance can be achieved by using a carbon nanotube structure and a carbon nanotube TFT with a particular structure. Further, the present inventors have found that variations in performance against bending can be decreased in a flexible TFT, leading to the present invention.

In order to achieve the above objects, a carbon nanotube structure according to the present invention comprises a metal thin film, a carbon nanotube thin film, and an organic conductive polymer thin film, thereby, a carbon nanotube structure with low contact resistance can be obtained. Also, a carbon nanotube TFT comprising the above carbon nanotube structure comprising source/drain electrodes as the above metal thin film, in regions where a channel and the source/drain electrodes overlap, has a small change in properties against bending. An increase in contact resistance when the carbon nanotube thin film is formed on the electrode is caused because the control of the contact points between the electrode and the carbon nanotube thin film is difficult due to elongated carbon nanotubes.

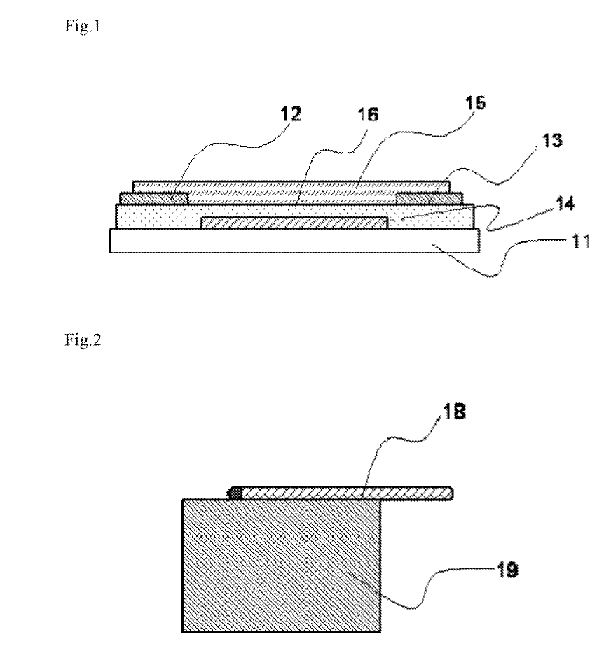

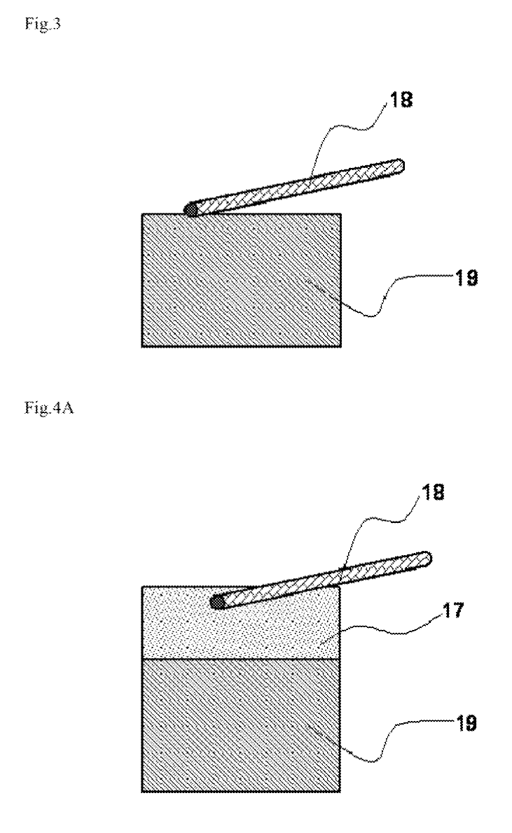

When the carbon nanotube is in parallel contact with the surface of the electrode, as shown in FIG. 2, there are many contact points between the electrode and the carbon nanotube, and charges can be easily transferred between the electrode and the carbon nanotube. But, when the carbon nanotube is in oblique contact with the surface of the electrode, as shown in FIG. 3, there is only one contact point between the electrode and the carbon nanotube, and the transfer of charges is unstable, as a result, causing an increase in contact resistance. When the carbon nanotube thin film is formed by a coating process, it is not easy to perform even the control of the arrangement of carbon nanotubes on the electrode surface, and the control of the contact points between the electrode surface and the carbon nanotubes is not sufficient.

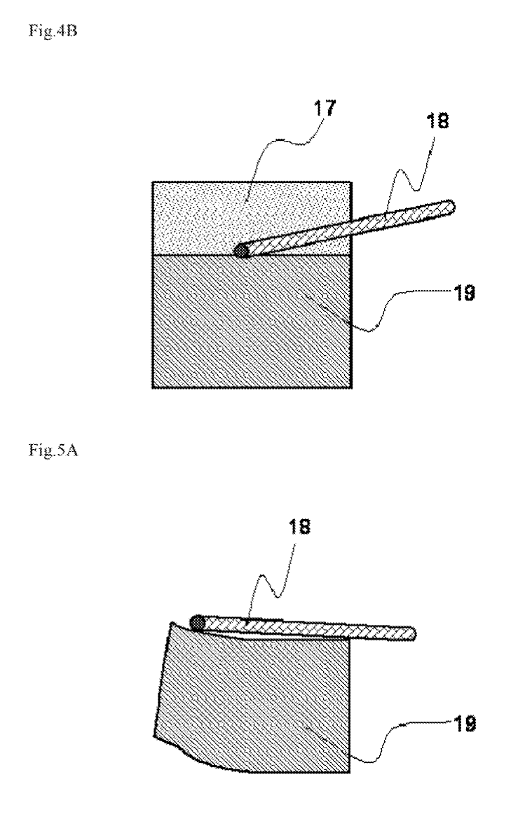

In the present invention, the organic conductive polymer thin film is formed on or under the carbon nanotube thin film, as shown in FIGS. 4A and 4B, thereby, the carbon nanotubes can effectively transfer charges, and the contact resistance can be reduced. Also, in a case where the contact points decrease when the substrate bends as shown in FIG. 5A, stable element properties can be achieved without increasing the contact resistance, as shown in FIG. 5B, by using an organic conductive polymer thin film with high flexibility.

When the carbon nanotube structure of the present invention comprises a metal thin film, a carbon nanotube thin film, and an organic conductive polymer thin film, and the carbon nanotube thin film and the organic conductive polymer thin film are in contact with each other, the contact resistance between the metal electrode and the carbon nanotube thin film can be decreased. For lamination order, the metal thin film, the carbon nanotube thin film, and the organic conductive polymer thin film may be laminated in this order, or the metal thin film, the organic conductive polymer thin film, and the carbon nanotube thin film may be laminated in this order. Also, the above metal thin film, the above carbon nanotube thin film, and the above organic conductive polymer thin film may be formed on an insulating material.

When the metal thin film, the carbon nanotube thin film, and the organic conductive polymer thin film are laminated in this order, the carbon nanotubes are covered with the organic conductive polymer thin film, as shown in FIG. 4B, and therefore, sufficient charge transfer sites can be held. When the metal thin film, the organic conductive polymer thin film, and the carbon nanotube thin film are laminated in this order, the organic conductive polymer thin film has more space than the electrode surface, and the elongated carbon nanotubes are buried in the organic conductive polymer thin film to some extent, as shown in FIG. 4A. Therefore, also in this case, the carbon nanotube structure can have sufficient charge transfer sites.

The organic conductive polymer thin film can be formed by applying an application liquid containing an appropriate organic conductive polymer, and drying and removing the application liquid. The carbon nanotube thin film can be formed by various methods, and can be formed by applying an application liquid containing carbon nanotubes, and drying and removing the application liquid.

In the above application liquids, water and general organic solvents can be used as the solvent in which the organic conductive polymer or the carbon nanotubes are dissolved or dispersed. Examples of the general organic solvents include alcohol solvents, such as methanol, halogen solvents, such as chloroform, ester solvents, such as ethyl acetate, aromatic solvents, such as toluene, and the like. But, as long as a solution or dispersion of an organic conductive polymer or carbon nanotubes can be formed, any solvent may be used, and the type of the solvent is not limited.

Also for the method for applying the application liquid of an organic conductive polymer or carbon nanotubes, plate printing, such as casting, typography, and screen printing, and plateless printing using a dispenser or an ink jet apparatus can be applied, and the application method is not limited.

When the carbon nanotube structure is formed by laminating a metal thin film, an organic conductive polymer thin film formed from a first application liquid containing an organic conductive polymer, and a carbon nanotube thin film formed from a second application liquid containing carbon nanotubes, in this order, the first application liquid containing an organic conductive polymer is applied, then, the second application liquid containing carbon nanotubes is applied before the first application liquid is completely dried and removed, and the first and second application liquids are dried and removed to form films, thereby, the coverage of the organic conductive polymer around the carbon nanotubes is improved, and the properties can be stabilized.

For the organic conductive polymer material forming the organic conductive polymer thin film, polymer materials with some conductivity can be applied, but polymer materials comprising polypyrrole, polyaniline, polyacetylene, or polythiophene with higher conductivity as the main chain are preferably used.

Also, by containing one or more donors selected from molecular donors and ionic donors, or one or more acceptors selected from molecular acceptors and ionic acceptors, as a dopant, in the organic conductive polymer thin film, a further improvement in conductivity can be intended. Molecules, such as iodine, tetrathiafulvalene, and tetracyanoquinodimethane, as well as ionic materials, such as sodium sulfonate compounds, can be used as the molecular donor, the ionic donor, the molecular acceptor, and the ionic acceptor.

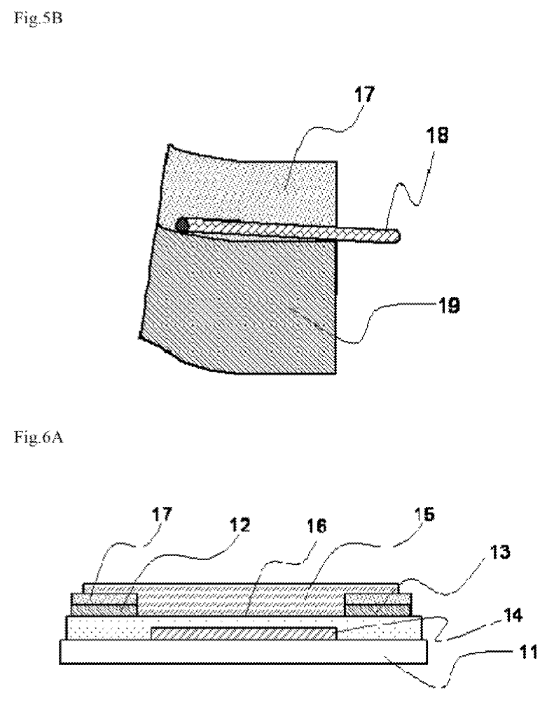

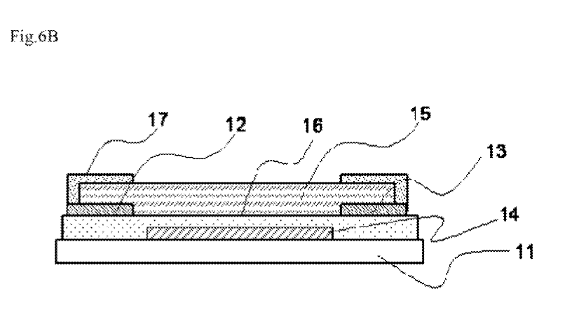

Further, a TFT comprising source/drain electrodes spaced from each other, a channel, and a gate electrode spaced from the above source/drain electrodes and being in contact with the above channel via a gate insulating film comprises the above carbon nanotube structure comprising the above source/drain electrodes as the above metal thin film, in regions where the above channel and the above source/drain electrodes overlap, thereby, a carbon nanotube TFT with excellent electrical properties can be obtained. A general carbon nanotube TFT has a structure as shown in FIG. 1, as described above. By applying the above-described carbon nanotube structure to the carbon nanotube TFT of the present invention, source/drain electrodes shown in FIGS. 6A and 6B have a structure in which an organic conductive polymer thin film is laminated in the upper portion or the lower portion. By applying the carbon nanotube structure comprising source/drain electrodes as the above metal thin film, with low contact resistance, a carbon nanotube ITT with excellent electrical properties can be obtained. At this time, the material of the above channel can comprise carbon nanotubes with semiconductor properties. Also, the material of the above channel can form the carbon nanotube thin film in the above carbon nanotube structure.

For this carbon nanotube TFT, when the carbon nanotubes of the electrode portions and the carbon nanotubes of the channel portion are formed from the same application liquid in the same step, the carbon nanotube TFT of the present invention can be conveniently obtained. The organic conductive polymer thin film is formed in a different step from that of the carbon nanotube thin film, and therefore, the carbon nanotube TFT can be obtained without comprising the organic conductive polymer thin film in the channel portion.

In the carbon nanotube TFT of the present invention, the source/drain electrodes, the organic conductive polymer thin film, and the carbon nanotube thin film may be formed in this order, or the source/drain electrodes, the carbon nanotube thin film, and the organic conductive polymer thin film may be formed in this order for the above carbon nanotube structure portion. This is similar to the case of the above-described carbon nanotube structure. Also, when the source/drain electrodes, the organic conductive polymer thin film, and the carbon nanotube thin film are formed in this order, a first application liquid containing an organic conductive polymer is applied, then, a second application liquid containing carbon nanotubes is applied before the first application liquid is completely dried and removed, and the first and second application liquids are dried and removed to form films, thereby, the properties can be further stabilized, as in the above-described carbon nanotube structure.

A flexible insulating substrate can be used as the substrate of the carbon nanotube TFT of the present invention. For example, a plastic film can be used as the flexible insulating substrate. Also when a plastic film is used for the substrate, the organic conductive polymer thin film covers the carbon nanotubes, as in the carbon nanotube structure. Therefore, a carbon nanotube TFT with stable properties against bending can be obtained.

Materials similar to those in the carbon nanotube structure can be applied to the material of the organic conductive polymer thin film used in the carbon nanotube TFT of the present invention. Also, the carbon nanotube TFT of the present invention has a structure that can stabilize the resistance between the electrodes and the carbon nanotubes, which are the channel, and electrical properties, and does not limit processes for fabricating other constituent parts. Therefore, they can be manufactured by vacuum deposition, sputtering, application, and the like, which are general thin film manufacturing methods.

The present invention will be described below in more detail, referring to the drawings and the like, and illustrating one example of an exemplary embodiment. FIGS. 4A and 4B are cross-sectional views showing one example of the configuration of a carbon nanotube structure in an exemplary embodiment. FIGS. 6A and 6B are cross-sectional views showing one example of the configuration of a carbon nanotube TFT in an exemplary embodiment.

The carbon nanotube structure in the exemplary embodiment comprises a metal thin film 19, an organic conductive polymer thin film 17, and a carbon nanotube 18, as shown in FIGS. 4A and 4B. The carbon nanotube structure can exhibit stable contact properties because the metal thin film 19 and the carbon nanotube 18 in any location are covered with the organic conductive polymer thin film 17 to some extent.

The carbon nanotube TFT in the exemplary embodiment comprises a pair of a source electrode 12 and a drain electrode 13, as shown in FIGS. 6A and 6B. For the contact sites between the source electrode 12 and the drain electrode 13 and a carbon nanotube thin film 15, the carbon nanotube TFT comprises the organic conductive polymer thin film 17 on or under the carbon nanotube thin film 15. The carbon nanotube thin film 15 is covered with the organic conductive polymer thin film 17 to some extent, as in the above carbon nanotube structure, and therefore, a TFT with stable excellent properties is obtained.

The material that can be used as a substrate 11 is not particularly limited as long as it is a material that can hold a TFT formed thereon, for example, inorganic materials, such as glass and silicon, and plastic materials, such as acrylic resins. Also, when the TFT structure can be sufficiently supported by a component other than the substrate, it is possible to use no substrate.

Examples of the materials that can be used for the source electrode 12, the drain electrode 13, a gate electrode 14, and the metal thin film 19 include, but are not limited to, metals and alloys, such as an indium tin oxide alloy (ITO), tin oxide (NESA), gold, silver, platinum, copper, indium, aluminum, magnesium, a magnesium-indium alloy, a magnesium-aluminum alloy, an aluminum-lithium alloy, an aluminum-scandium-lithium alloy, and a magnesium-silver alloy, as well as organic materials, such as conductive polymers.

The carbon nanotube layer 15 is formed from carbon nanotubes, but a mixture containing carbon nanotubes can also be used. The mixture is not particularly limited as long as it exhibits semiconductor properties. Examples of the carbon nanotubes used in the present invention include single-wall carbon nanotubes (SWNTs), double-wall carbon nanotubes (DWNTs), and multi-wall carbon nanotubes (MWNTs). Particularly, SWNTs and DWNTs exhibiting semiconductor properties are preferably used. But, the carbon nanotubes are not limited to these.

For the length of the carbon nanotube, various carbon nanotubes with a length of about 4 nm to a length of about 10 μm are present, and the semiconductor properties are not defined by length. But, carbon nanotubes with a length of about 50 nm to 2 μm are preferably used in view of the stability of the application liquid, and the convenience of handling.

For the thickness of the carbon nanotube, carbon nanotubes with a thickness of about 0.4 nm to a thickness of about 4 nm are present. The target element can be obtained using carbon nanotubes with any thickness. But, carbon nanotubes with a thickness of 0.5 nm to 2 nm are preferably used in view of the chemical stability and mechanical stability of the carbon nanotubes.

Inorganic compounds, such as a silicon dioxide film and a silicon nitride film, as well as organic insulating materials, such as acrylic resins and polyimide, can be used as the material that can be used for a gate insulating film 16. But, any material with electrical insulation can be used, and the material is not particularly limited.

Examples of the material that can be used for the organic conductive polymer thin film 17 include polymer materials comprising polypyrrole, polyaniline, polyacetylene, or polythiophene as the main chain, and the like. But, the material is not particularly limited as long as it is a polymer having conductivity in a normal state. As in the above, molecules, such as iodine, tetrathiafulvalene, and tetracyanoquinodimethane, as well as ionic materials, such as sodium sulfonate compounds, can be used as the molecular donor, the ionic donor, the molecular acceptor, and the ionic acceptor that can be used in the organic conductive polymer thin film 17.

Common electrode forming processes, such as vacuum deposition, sputtering, etching, and lift-off, can be used as the methods for fabricating the source electrode 12, the drain electrode 13, the gate electrode 14, and the metal thin film 19, and the methods are not particularly limited. When organic materials, such as conductive polymers, dispersions comprising a silver paste or metal particles, and metal organic compounds, are used as the electrodes, solution processes, such as spin coating, dipping, a dispenser method, and an ink jet method, can also be used, and the methods are not particularly limited.

In addition to solution processes, such as spin coating, dipping, a dispenser method, and an ink jet method, direct growth methods, such as CVD, can also be used as the method for forming the carbon nanotube thin film layer 15.

In addition to dry processes, such as vacuum deposition and sputtering, solution processes, such as spin coating, dipping, a dispenser method, and an ink jet method, can also be used as the method for forming the gate insulating film 16, and the method is not particularly limited.

In addition to solution processes, such as spin coating, dipping, a dispenser method, and an ink jet method, CVD, vacuum deposition, and the like can also be used as the method for forming the organic conductive polymer thin film 17.

The film thickness of the carbon nanotube thin film 15 in the carbon nanotube structure and carbon nanotube TFT of the present invention is no particularly limited. For the carbon nanotube thin film, as long as a network in which the contained carbon nanotubes are in contact with each other is formed, even a monolayer film can be used. In this case, the film thickness of the carbon nanotube thin film is about 1 μm to 2 μm. But, a film thickness of 1 μm is preferred because if the carbon nanotube thin film is too thick, the control of current flowing through the element is difficult.

The film thickness of the organic conductive polymer thin film 17 is not particularly limited, but is preferably in the range of 10 nm to 500 nm in view of cost and the convenience of the manufacturing process.

### EXAMPLES

The present invention will be described below in detail, based on Examples, but the present invention is not limited to the following Examples.

### Example 1

In this Example, the carbon nanotube structure in FIG. 4A described in the exemplary embodiment was fabricated by the following procedure. First, a chromium film was formed in the shape of a strip with a width of 2 mm, with a film thickness of 100 nm, on a glass substrate by vacuum deposition to provide the metal thin film 19. Then, a film of a xylene solution of polythiophene (manufactured by Aldrich) containing iodine as a dopant, with a film thickness of 100 nm, was formed directly on this metal thin film 19, using a dispenser apparatus, to provide the organic conductive polymer thin film 17. Further, before the solvent of the polythiophene thin film was completely dry, a carbon nanotube thin film was manufactured using a dimethylformamide dispersion of carbon nanotubes (manufactured by Aldrich) to obtain a carbon nanotube structure 101. The carbon nanotube thin film was formed in a shape with a width of 1 mm and a length of 20 mm, orthogonal to the strip of the metal thin film 19, using a dispenser apparatus.

Apart from the carbon nanotube structure 101, a carbon nanotube structure was fabricated as in the above, except that the organic conductive polymer thin film 17 was not provided, to obtain a carbon nanotube structure 201.

A probe was placed at an end of the chromium strip, the metal thin film, and an end of the carbon nanotube strip, and current flowing at the intersection of the chromium strip and the carbon nanotube strip was measured. With current flowing through the carbon nanotube structure 201 being 1, current flowing through the carbon nanotube structure 101 was evaluated as the ratio of the current value of 101 to the above 201. The current of the carbon nanotube structure 101 was 38, and an improvement in flowing current value was seen. The result is shown in Table 1.

### Examples 2 to 5

Carbon nanotube structures were fabricated exactly as in Example 1, except that compounds shown in Table 1 were used as the organic conductive polymer thin film material, to obtain carbon nanotube structures 102 to 105. The ratio to the carbon nanotube structure 201 was evaluated as in Example I for the fabricated carbon nanotube structures 102 to 105. Results shown in Table 1 were obtained, and an improvement in current value was seen. For polyaniline, polypyrrole, and polyacetylene, polyaniline (manufactured by Aldrich), polypyrrole (manufactured by Aldrich), and polyacetylene (synthesized by a method described in H. Shirakawa et al., J. Chem. Soc. Chem. Commun., p. 578, 1977) were used.

TABLE 1

| | Organic conductive | Carbon | Ratio of |
|---|---|---|---|
| | polymer thin film | nanotube | current |
| Example | material/dopant | structure | value to 201 |
| 1 | Polythiophene/iodine | 101 | 38 |
| 2 | Polyaniline/sodium | 102 | 24 |
| | para-toluene sulfonate | | |
| 3 | Polypyrrole/iodine | 103 | 18 |
| 4 | Polypyrrole/sodium | 104 | 30 |
| | para-toluene sulfonate | | |
| 5 | Polyacetylene/sodium | 105 | 11 |
| | para-toluene sulfonate | | |

### Example 6

In this Example, the carbon nanotube structure in FIG. 4B described in the exemplary embodiment was fabricated by the following procedure. First, a gold film was formed in the shape of a strip with a width of 2 mm, with a film thickness of 100 nm, on a polyethylene naphthalate substrate, a plastic substrate, by vacuum deposition to provide the metal thin film 19. Then, a carbon nanotube thin film was manufactured using a dimethylformamide dispersion of carbon nanotubes (manufactured by Aldrich). The carbon nanotube thin film was formed in a shape with a width of 1 mm and a length of 20 mm, orthogonal to the strip of the metal thin film 19, using a dispenser apparatus. Further, a film of a xylene solution of polythiophene (manufactured by Aldrich) containing iodine as a dopant, with a film thickness of 100 nm, was formed directly on the intersection of this metal thin film 19 and the carbon nanotube, using a dispenser apparatus, to obtain a carbon nanotube structure 106.

Apart from the carbon nanotube structure 106, a carbon nanotube structure was fabricated as in the above, except that the organic conductive polymer thin film 17 was not provided, to obtain a carbon nanotube structure 202.

A probe was placed at an end of the gold strip, the metal thin film, and an end of the carbon nanotube strip, and current flowing at the intersection of the gold strip and the carbon nanotube strip was measured. With current flowing through the carbon nanotube structure 202 being 1, current flowing through the carbon nanotube structure 106 was evaluated as the ratio of the current value of 106 to 202. The current of the carbon nanotube structure 106 was 84, and an improvement in flowing current value was seen.

### Examples 7 to 10

Carbon nanotube structures were fabricated exactly as in Example 6, except that compounds shown in Table 2 were used as the organic conductive polymer thin film material, to obtain carbon nanotube structures 107 to 110. The ratio to the carbon nanotube structure 202 was evaluated as in Example 6 for the fabricated carbon nanotube structures 107 to 110. Results shown in Table 2 were obtained, and an improvement in current value was seen. For polyaniline, polypyrrole, and polyacetylene, polyaniline (manufactured by Aldrich), polypyrrole (manufactured by Aldrich), and polyacetylene (synthesized by the method described in H. Shirakawa et al., J. Chem. Soc. Chem. Commun., p. 578, 1977) were used.

TABLE 2

| | Organic conductive | Carbon | Ratio of |
|---|---|---|---|
| | polymer thin film | nanotube | current |
| Example | material/dopant | structure | value to 202 |
| 6 | Polythiophene/iodine | 106 | 84 |
| 7 | Polyaniline/sodium | 107 | 102 |
| | para-toluene sulfonate | | |
| 8 | Polypyrrole/iodine | 108 | 56 |
| 9 | Polypyrrole/sodium | 109 | 78 |
| | para-toluene sulfonate | | |
| 10 | Polyacetylene/sodium | 110 | 64 |
| | para-toluene sulfonate | | |

### Comparative Example 1

The carbon nanotube structure 202 was wound around a cylinder with a diameter of 2 cm, and the current value before winding and the current value after winding were measured. The current value after winding was 0.75 of the current value before winding.

### Example 11

The carbon nanotube structure 106 was subjected to a test similar to that of Comparative Example 1. The current value after the carbon nanotube structure 106 was wound around the cylinder was 0.97 of the current value before winding, and the amount of change was smaller than that of Comparative Example 1.

### Example 12

In this Example, the carbon nanotube TFT in FIG. 6A described in the exemplary embodiment was fabricated by the following procedure. First, a 10 nm chromium film was manufactured on the glass substrate 11 by vacuum deposition, and a 90 nm gold film was manufactured by vacuum deposition to provide the gate electrode 14. A silicon dioxide film with a film thickness of 200 nm was formed on the gate electrode 14 by sputtering to provide the insulator layer 16. A 10 nm chromium film was manufactured on the insulator layer 16 by vacuum deposition, and a 90 nm gold film was manufactured by vacuum deposition to form the source electrode 12 and the drain electrode 13. The source electrode 12 and the drain electrode 13 were manufactured using a metal shadow mask, and located at an interval of 300 μm. A film of a xylene solution of polythiophene (manufactured by Aldrich) containing iodine as a dopant, with a film thickness of 100 nm, was formed directly on the source electrode 12 and the drain electrode 13, using a dispenser apparatus, to provide the organic conductive polymer thin film 17. Further, before the solvent of the polythiophene thin film was completely dry, the carbon nanotube thin film 15 was manufactured using a dimethylformamide dispersion of carbon nanotubes (manufactured by Aldrich) to obtain a carbon nanotube TFT 301. The carbon nanotube thin film 15 was formed on and between the source and drain electrodes, with a channel width of 2 mm, using a dispenser apparatus.

Apart from the carbon nanotube TFT 301, a carbon nanotube TFT was fabricated as in the above, except that the organic conductive polymer thin film 17 was not provided, to obtain a carbon nanotube TFT 401.

The source-drain current value when 10 V was applied for the source-drain voltage and −2 V was applied for the gate voltage was measured. With the current value of the carbon nanotube TFT 401 being 1, the current value of the carbon nanotube TFT 301 was evaluated as the ratio of the current value of 301 to 401. The current of the carbon nanotube TFT 301 was 52, and an improvement in element properties was seen.

### Examples 13 to 16

Carbon nanotube TFTs were fabricated exactly as in Example 12, except that compounds shown in Table 3 were used as the organic conductive polymer thin film material, to obtain carbon nanotube TFTs 302 to 305. The ratio to the carbon nanotube TFT 401 was evaluated as in Example 12 for the fabricated carbon nanotube TFTs 302 to 305. Results shown in Table 3 were obtained, and an improvement in element properties was seen. For polyaniline, polypyrrole, and polyacetylene, polyaniline (manufactured by Aldrich), polypyrrole (manufactured by Aldrich), and polyacetylene (synthesized by the method described in H. Shirakawa et al., J. Chem. Soc. Chem. Commun., p. 578, 1977) were used.

TABLE 3

| | Organic conductive | Carbon | Ratio of |
|---|---|---|---|
| | polymer thin film | nanotube | current |
| Example | material/dopant | structure | value to 401 |
| 12 | Polythiophene/iodine | 301 | 52 |
| 13 | Polyaniline/sodium | 302 | 36 |
| | para-toluene sulfonate | | |
| 14 | Polypyrrole/iodine | 303 | 41 |
| 15 | Polypyrrole/sodium | 304 | 26 |
| | para-toluene sulfonate | | |
| 16 | Polyacetylene/sodium | 305 | 34 |
| | para-toluene sulfonate | | |

### Example 17

In this Example, the carbon nanotube TFT in FIG. 6B described in the exemplary embodiment was fabricated by the following procedure. First, a 100 nm gold film was manufactured on the polyethylene naphthalate substrate 11, a plastic material, by vacuum deposition to provide the gate electrode 14. A silicon dioxide film with a film thickness of 200 nm was formed on the gate electrode 14 by sputtering to provide the insulator layer 16. A 10 nm chromium film was manufactured on the insulator layer 16 by vacuum deposition, and a 90 nm gold film was manufactured by vacuum deposition to form the source electrode 12 and the drain electrode 13. The source electrode 12 and the drain electrode 13 were manufactured using a metal shadow mask, and located at an interval of 300 μm. Then, the carbon nanotube thin film 15 was manufactured using a dimethylformamide dispersion of carbon nanotubes (manufactured by Aldrich) to form a carbon nanotube channel. The carbon nanotube thin film 15 was formed on and between the source and drain electrodes, with a channel width of 2 mm, using a dispenser apparatus. Further, the organic conductive polymer thin film 17 with a film thickness of 100 nm was formed directly on the intersections of the carbon nanotube channel and the source and drain electrodes, with a xylene solution of polythiophene (manufactured by Aldrich) containing iodine as a dopant, using a dispenser apparatus. Thus, a carbon nanotube TFT 306 was obtained.

Apart from the carbon nanotube TFT 306, a carbon nanotube TFT was fabricated as in the above, except that the organic conductive polymer thin film 17 was not provided, to obtain a carbon nanotube TFT 402.

The source-drain current value when 10 V was applied for the source-drain voltage and −2 V was applied for the gate voltage was measured. With the current value of the carbon nanotube TFT 402 being 1, the current value of the carbon nanotube TFT 306 was evaluated as the ratio of the current value of 306 to 402. The current of the carbon nanotube TFT 306 was 189, and an improvement in element properties was seen.

### Examples 18 to 21

Carbon nanotube TFTs were fabricated exactly as in Example 17, except that compounds shown in Table 4 were used as the organic conductive polymer thin film material, to obtain carbon nanotube TFTs 307 to 310. The ratio to the carbon nanotube TFT 402 was evaluated as in Example 17 for the fabricated carbon nanotube TFTs 307 to 310. Results shown in Table 4 were obtained, and an improvement in current value was seen. For polyaniline, polypyrrole, and polyacetylene, polyaniline (manufactured by Aldrich), polypyrrole (manufactured by Aldrich), and polyacetylene (synthesized by the method described in H. Shirakawa et al., J. Chem. Soc. Chem. Commun., p. 578, 1977) were used.

TABLE 4

| | Organic conductive | Carbon | Ratio of |
|---|---|---|---|
| | polymer thin film | nanotube | current |
| Example | material/dopant | structure | value to 402 |
| 17 | Polythiophene/iodine | 306 | 189 |
| 18 | Polyaniline/sodium | 307 | 215 |
| | para-toluene sulfonate | | |
| 19 | Polypyrrole/iodine | 308 | 97 |
| 20 | Polypyrrole/sodium | 309 | 143 |
| | para-toluene sulfonate | | |
| 21 | Polyacetylene/sodium | 310 | 78 |
| | para-toluene sulfonate | | |

### Comparative Example 2

The carbon nanotube TFT 402 was wound around a cylinder with a diameter of 2 cm. The current value before winding, and the source-drain current value when 10 V was applied for the source-drain voltage and −2 V was applied for the gate voltage after winding were measured. The current value after winding was 0.42 of the current value before winding.

### Example 22

The carbon nanotube TFT 306 was subjected to a test similar to that of Comparative Example 2. The current value after the carbon nanotube TFT 306 was wound around the cylinder was 0.88 of the current value before winding, and the amount of change was smaller than that of Comparative Example 2.

The present invention has been described, based on the exemplary embodiments, but the thin film transistor according to the present invention is not limited only to the configurations in the above exemplary embodiments.

This application claims priority to Japanese Patent Application No. 2007-232603 filed Sep. 7, 2007, the entire disclosure of which is incorporated herein.

The invention of this application has been described with reference to the exemplary embodiments (and Examples), but the invention of this application is not limited to the above exemplary embodiments (and Examples). Various changes that can be understood by those skilled in the art can be made in the configuration and detail of the invention of this application within the scope of the invention of this application.

1. A carbon nanotube structure characterized by comprising a metal thin film, a carbon nanotube thin film, and an organic conductive polymer thin film, the carbon nanotube thin film and the organic conductive polymer thin film being in contact with each other.

2. The carbon nanotube structure according to claim 1, characterized in that the organic conductive polymer thin film comprises an organic conductive polymer containing, as a main chain, at least one polymer selected from the group consisting of polypyrrole, polyaniline, polyacetylene, and polythiophene.

3. The carbon nanotube structure according to claim 1, characterized in that the organic conductive polymer thin film contains, as a dopant, one or more donors selected from molecular donors and ionic donors, or one or more acceptors selected from molecular acceptors and ionic acceptors.

4. The carbon nanotube structure according to claim 1, wherein the organic conductive polymer thin film is formed by applying an application liquid containing an organic conductive polymer.

5. The carbon nanotube structure according to claim 1, wherein the carbon nanotube thin film is formed by applying an application liquid containing a carbon nanotube.

6. The carbon nanotube structure according to claim 1, wherein the metal thin film, the carbon nanotube thin film, and the organic conductive polymer thin film are formed on an insulating material.

7. The carbon nanotube structure according to claim 6, formed by laminating the metal thin film, the carbon nanotube thin film, and the organic conductive polymer thin film in this order on the insulating material.

8. The carbon nanotube structure according to claim 6, formed by laminating the metal thin film, the organic conductive polymer thin film, and the carbon nanotube thin film in this order on the insulating material.

9. The carbon nanotube structure according to claim 8, wherein the organic conductive polymer thin film and the carbon nanotube thin film are formed by applying an first application liquid containing an organic conductive polymer, applying a second application liquid containing a carbon nanotube before a solvent or a dispersion medium included in the first application liquid is completely removed, and removing the solvent or the dispersion medium included in the first application liquid, and a solvent or a dispersion medium included in the second application liquid.

10. A thin film transistor comprising source/drain electrodes spaced from each other, a channel, and a gate electrode spaced from the source/drain electrodes and being in contact with the channel via a gate insulating film,
comprising a carbon nanotube structure according to claim 1, comprising the source/drain electrodes as the metal thin film, in regions where the channel and the source/drain electrodes overlap.

11. The thin film transistor according to claim 10, characterized in that the material of the channel comprises a carbon nanotube with semiconductor properties.

12. The thin film transistor according to claim 11, wherein the material of the channel forms the carbon nanotube thin film in the carbon nanotube structure.

13. The thin film transistor according to claim 10, formed on a flexible insulating substrate.

14. The thin film transistor according to claim 13, wherein the flexible insulating substrate is a plastic film.
